(19) United States
(12) Patent Application Publication
(10) Pub. No.: US 2008/0121924 A1
(43) Pub. Date: May 29, 2008

(54) APPARATUS FOR MANUFACTURING GROUP III NITRIDE COMPOUND SEMICONDUCTOR LIGHT-EMITTING DEVICE, METHOD OF MANUFACTURING GROUP III NITRIDE COMPOUND SEMICONDUCTOR LIGHT-EMITTING DEVICE, GROUP III NITRIDE COMPOUND SEMICONDUCTOR LIGHT-EMITTING DEVICE, AND LAMP

(75) Inventors: Hisayuki Miki, Chiba-shi (JP); Kenzo Hanawa, Ichihara-shi (JP); Yasumasa Sasaki, Kamakura-shi (JP); Yasunori Yokoyama, Ichihara-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku (JP)

(21) Appl. No.: 11/943,542

(22) Filed: Nov. 20, 2007

(30) Foreign Application Priority Data
Nov. 24, 2006 (JP) 2006-317023
Sep. 11, 2007 (JP) 2007-235412

(51) Int. Cl. H01L 33/00; C23C 14/34

(52) U.S. Cl. 257/103; 438/45; 204/298.13; 257/E33.023

(57) ABSTRACT

A Group III nitride compound semiconductor light-emitting device manufacturing apparatus with a simple structure, which it is capable of easily optimizing the density of a dopant element in the crystals of a Group III nitride compound semiconductor and forming layers with high efficiency using a sputtering method. The manufacturing apparatus includes: a chamber; a Ga target containing a Ga element and a dopant target containing a dopant element, the Ga target and the dopant target being placed within the chamber; and a power application unit that applies power to the Ga target and the dopant target simultaneously or alternately.

### BACKGROUND OF THE INVENTION

1. Field of the Invention

The present invention relates to an apparatus for manufacturing a Group III nitride compound semiconductor light-emitting device adaptable to light-emitting diodes (LEDs), laser diodes (LDs), other electronic devices, a method of manufacturing a Group III nitride compound semiconductor light-emitting device, a Group III nitride compound semiconductor light-emitting device, and a lamp employing the Group III nitride compound semiconductor light-emitting device.

Priority is claimed on Japanese Patent Application No. 2006-317023, filed Nov. 24, 2006, and Japanese Patent Application No. 2007-235412, filed Sep. 11, 2007, the contents of which are incorporated herein by reference.

2. Description of the Related Art

A Group III nitride compound semiconductor light-emitting device, which has a direct transition-type energy band gap corresponding to a range from a visible wavelength to an ultraviolet wavelength, is being used as a light-emitting device, such as an LED or an ID, because of its high emission efficiency.

A Group III nitride compound semiconductor makes it possible to obtain an electronic device having highly desirable characteristics as compared to a conventional Group III-V compound semiconductor.

Such a Group III nitride compound semiconductor is generally manufactured by a MOCVD method using trimethyl gallium, trimethyl aluminum, and ammonia as the raw materials.

The MOCVD method includes transporting a carrier gas including vaporized raw materials onto a substrate surface and growing a crystal by decomposing the raw materials by the reaction with the heated substrate.

Studies of manufacturing crystals of a Group III nitride compound semiconductor by means of sputtering have been made. Specifically, for example, a method of forming a GaN layer on a Si (100) surface and a sapphire (A₂O₃) (0001) surface by means of a radio frequency (RF) sputtering method using a N₂ gas has been proposed (for example, see Y. USHIKU et al., ‘Proceedings of the 21^{st} Century Combined Symposium’, Vol. 2^{nd}, p 295 (2003)).

In addition, a method of forming a GaN layer by means of an apparatus having a mesh interposed between a substrate and a solid state target, with the target opposed to a cathode, has been proposed (for example, see T. Kikuma et al., ‘Vacuum’, Vol. 66, p 233 (2002)).

When forming the crystals of the Group III nitride compound semiconductor composed of GiN, there is a need to form crystals with a dopant, such as Si or Mg, doped in the GaN layer. To meet such a need, a method of forming a GaN layer by means of a sputtering method using a target obtained by mixing a Ga element as a basic material with a dopant has been proposed (for example, see The Japan Society of Applied Physics Edition, ‘The 66^{th} Japan Society of Applied Physics’ Pamphlet, 7a-N-6, Fascicle 1, p 243 (Autumn 2005)).

However, it is difficult for the conventional sputtering methods to finely adjust the doping density when crystals of a doped Group III nitride compound semiconductor are formed.

In addition, when an AlGaN layer doped with Mg is formed using the MOCVD method, the amount of Mg injected into crystals varies depending on the composition of Al. That is, a low composition of Al facilitates the injection of Mg into the crystals while a high composition of Al makes the injection of Mg into the crystals difficult.

In addition, in the method disclosed in Non-Patent Document 3, which uses the target obtained by mixing Ga as the basic material with the dopant, when a layer that contains the dopant and a layer that does not contain the dopant are successively formed on a substrate, it is required to form these layers on the substrate by means of sputtering using a plurality of chambers while moving the substrate between the plurality of chambers. This may lead to a problem of increasing in size of the sputter and prolongation of the process time.

Moreover, the method disclosed in Non-Patent Document 3 has no specified explanation about how to dope the dopant. In addition, in this method, when the dopant is mixed with Ga which is liquefied at room temperature, since the dopant in the mixture rises or sinks because of a specific gravity difference between the dopant and Ga, it is difficult to obtain uniform density of the dopant in crystals of an obtained gallium nitride semiconductor. To avoid this difficulty, it may be considered to form the GaN layer using the sputtering method while preventing Ga from being liquefied. However, in this case, it may be difficult to supply sufficient power and obtain a sufficiently high film forming rate.

### SUMMARY OF THE INVENTION

To overcome the above problems, it is an object of the invention to provide an apparatus within a simple structure for manufacturing a Group III nitride compound semiconductor light emitting device, which is capable of facilitating optimization of the density of a dopant in crystals of a gallium nitride semiconductor and efficiently forming a film using a sputtering method.

It is another object of the invention to provide a method of manufacturing a Group III nitride compound semiconductor light-emitting device, which is capable of facilitating optimization of the density of a dopant in crystals of the Group III nitride semiconductor and efficiently forming a film using a sputtering method.

It is still another object of the invention to provide a Group III nitride compound semiconductor light-emitting device obtained by the above method and a lamp employing the obtained Group II nitride compound semiconductor light-emitting device.

The present inventors have reviewed the above problems and have devised an apparatus which is capable of applying power to a Ga target containing Ga and a dopant target containing a dopant simultaneously or alternately, thereby facilitating optimization of the density of a dopant in crystals of a gallium nitride semiconductor and efficiently forming a film using a sputtering method, without increase in the size of the apparatus.

The present invention concerns the following constitutions.

According to a first aspect of the invention, there is provided an apparatus for manufacturing a Group III nitride compound semiconductor light-emitting device including a semiconductor layer made of a Group III nitride semiconductor, using a sputtering method. The apparatus includes: a chamber; a Ga target containing a Ga element and a dopant target containing a dopant element, the Ga target and the dopant target being placed within the chamber; and a power application unit that applies power to the Ga target and the dopant target simultaneously or alternately.

According to a second aspect of the invention, in the apparatus according to the first aspect, preferably, the dopant element is Si or Mg.

According to a third aspect of the invention, in the apparatus according to the first or second aspect, preferably, the power application unit controls a ratio of the Ga element to the dopant element in a gas phase when the semiconductor layer is formed, by changing a ratio of power applied to the Ga target to power applied to the dopant target.

According to a fourth aspect of the invention, in the apparatus according to the first or second aspect, preferably, the power application unit applies pulse DC power and controls a ratio of the Ga element to the dopant element in a gas phase when the semiconductor layer is formed, by changing a pulse ratio of a pulse applied to the Ga target to a pulse applied to the dopant target.

According to a fifth aspect of the invention, in the apparatus according to the third or fourth aspect, preferably, the dopant element is Si and the power application unit controls a ratio of the Ga element to the Si element in the gas phase when the semiconductor layer is formed to fall within a range of 1:0.001 to 1:0.00001.

According to a sixth aspect of the invention, in the apparatus according to the third or fourth aspect, preferably, the dopant element is Mg and the power application unit controls a ratio of the Ga element to the Mg element in the gas phase when the semiconductor layer is formed to fall within a range of 1:0.1 to 1:0.001.

According to a seventh aspect of the invention, in the apparatus according to any one of the first to sixth aspects, preferably, at least a surface of the Ga target is liquefied.

According to an eighth aspect of the invention, in the apparatus according to any one of the first to seventh aspects, preferably, the dopant element is sputtered so that a cluster including a diatomic or more dopant element is not formed.

According to a ninth aspect of the invention, in the apparatus according to any one of the first to eighth aspects, preferably, the dopant element is sputtered at a voltage at which a cluster including a diatomic or more dopant element is not formed.

According to a tenth aspect of the invention, there is provided a method of manufacturing a Group III nitride compound semiconductor light-emitting device including a laminated semiconductor layer having an n type semiconductor layer, a light-emitting layer and a p type semiconductor layer, each made of a Group III nitride semiconductor. The method includes the steps of: forming at least some of the layers of the laminated semiconductor layer by a sputtering method; and applying power to a Ga target containing a Ga element and a dopant target containing a dopant element simultaneously or alternately when the laminated semiconductor layer is formed by the sputtering method, the Ga target and the dopant target being used as sputter targets.

According to an eleventh aspect of the invention, in the method according to the tenth aspect, preferably, the n type semiconductor layer is formed using Si as the dopant element.

According to a twelfth aspect of the invention, in the method according to the eleventh aspect, preferably, a ratio of the Ga element to the Si element in a gas phase when the n type semiconductor layer is formed falls within a range of 1:0.001 to 1:0.00001.

According to a thirteenth aspect of the invention, in the method according to the tenth aspect, preferably, the p type semiconductor layer is formed using Mg as the dopant element.

According to a fourteenth aspect of the invention, in the method according to the thirteenth aspect, preferably, a ratio of the Ga element to the Mg element in a gas phase when the p type semiconductor layer is formed falls within a range of 1:0.1 to 1:0.001.

According to a fifteenth aspect of the invention, in the method according to any one of the tenth to fourteenth aspects, preferably, the ratio of the Ga element to the dopant element in the gas phase when the semiconductor layer is formed is controlled by changing an area ratio of a surface of the Ga target facing a substrate to a surface of the dopant target facing the substrate.

According to a sixteenth aspect of the invention, in the method according to any one of the tenth to fourteenth aspects, preferably, the ratio of the Ga element to the dopant element in the gas phase when the semiconductor layer is formed is controlled by changing a ratio of power applied to the Ga target to power applied to the dopant target.

According to a seventeenth aspect of the invention, in the method according to any one of the tenth to fourteenth aspects, preferably, the ratio of the Ga element to the dopant element in the gas phase when the semiconductor layer is formed is controlled by changing a pulse ratio of the pulse of pulse DC power applied to the Ga target to the pulse of pulse DC power applied to the dopant target.

According to an eighteenth aspect of the invention, in the method according to any one of the tenth to seventeenth aspects, preferably, an intermediate layer consisting of columnar crystals is formed between the substrate and the semiconductor layer.

According to a nineteenth aspect of the invention, in the method according to any one of the tenth to eighteenth aspects, preferably, at least a surface of the Ga target is liquefied.

According to a twentieth aspect of the invention, there is provided a Group III nitride compound semiconductor light emitting device manufactured by the manufacturing method according to any one of the tenth to nineteenth aspects.

According to a twenty-first aspect of the invention, there is provided a lamp employing the Group III nitride compound semiconductor light emitting device according to the twentieth aspect.

According to the invention, the Group III nitride compound semiconductor light-emitting device manufacturing apparatus of the invention includes: the Ga target containing the Ga element and the dopant target containing the dopant element, which are placed within the chamber; and the power application unit that applies power to the Ga target and the dopant target simultaneously or alternately. According to the above-mentioned structure, it is possible to easily optimize the density of the dopant element in the crystals of the semiconductor layer to be formed using the sputtering method.

In addition, in the Group III nitride compound semiconductor light-emitting device manufacturing apparatus of the invention, since the Ga target and the dopant target are placed in the chamber, it is possible to continuously laminate a layer that contains the dopant element and a layer that does not contain the dopant element on the substrate in one chamber. Accordingly, it is possible to reduce the size of the apparatus of the invention, as compared to the conventional sputters in which one target is placed in one chamber, and it is possible to reduce the time required for a film forming process.

Further, since the Group III nitride compound semiconductor light-emitting device manufacturing apparatus of the invention uses the sputtering method to form films, the structure of the apparatus is simplified, and can form layers at a high speed and with high efficiency, as compared to conventional MOCVD and MBE methods.

Furthermore, in the Group III nitride compound semiconductor light-emitting device manufacturing method of the invention, when the semiconductor layer is formed by the sputtering method, power is applied to the Ga target containing the Ga element and the dopant target containing the dopant element, which are used as sputter targets, simultaneously or alternately, which makes it possible to easily optimize the density of the dopant element in the crystals of the Group III nitride compound semiconductor containing the Ga element and form layers with high efficiency using the sputtering method.

In addition, since the Group III nitride compound semiconductor light-emitting device and the lamp are manufactured by the manufacturing method of the invention, they have the optimal dopant density in crystals of the Group III nitride compound semiconductor containing the Ga element and hence excellent emission properties.

### BRIEF DESCRIPTION OF THE DRAWINGS

FIG. 1 is a schematic sectional view showing an exemplary Group III nitride compound semiconductor light-emitting device according to an embodiment of the invention.

FIG. 2 is a schematic view showing a planar structure of the Group III nitride compound semiconductor light-emitting device shown in FIG. 1.

FIG. 3 is a schematic view showing an exemplary apparatus for manufacturing a Group III nitride compound semiconductor light-emitting device according to an embodiment of the invention.

FIG. 4 is a schematic sectional view showing a laminated semiconductor for explaining a method of manufacturing the Group III nitride compound semiconductor light-emitting device shown in FIG. 1.

FIG. 5 is a schematic view showing an exemplary lamp employing a Group III nitride compound semiconductor light-emitting device according to an embodiment of the invention.

FIG. 6 is a schematic view showing another exemplary apparatus for manufacturing a Group III nitride compound semiconductor light-emitting device according to an embodiment of the invention.

### DETAILED DESCRIPTION OF THE INVENTION

Hereinafter, an apparatus for manufacturing a Group III nitride compound semiconductor light-emitting device, a method of manufacturing a Group III nitride compound semiconductor light-emitting device, a Group III nitride compound semiconductor light-emitting device, and a lamp employing the Group III nitride compound semiconductor light-emitting device according to exemplary embodiments of the invention will be described with reference to the accompanying drawings.

Group III Nitride Compound Semiconductor Light-Emitting Device

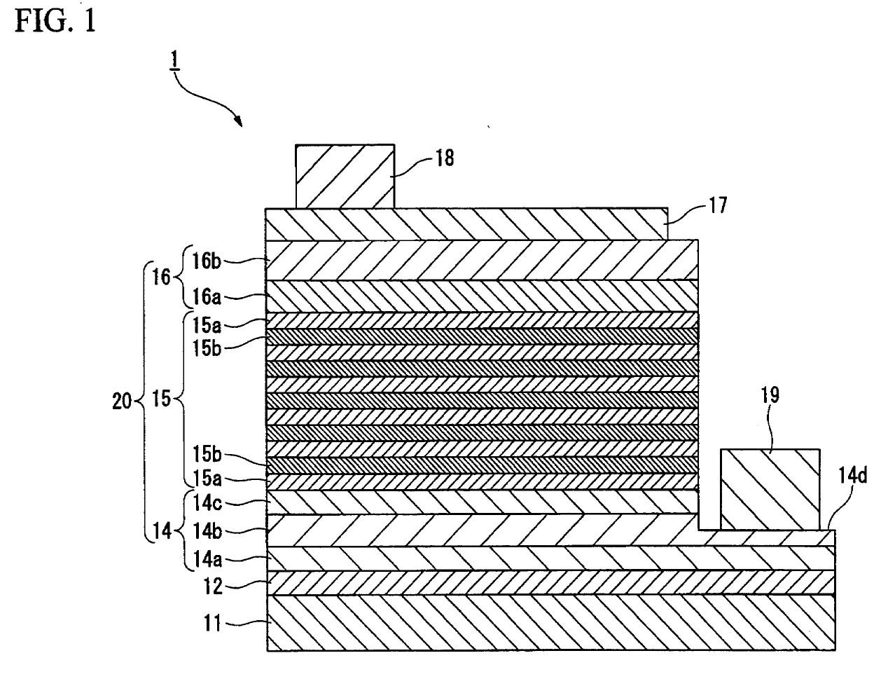

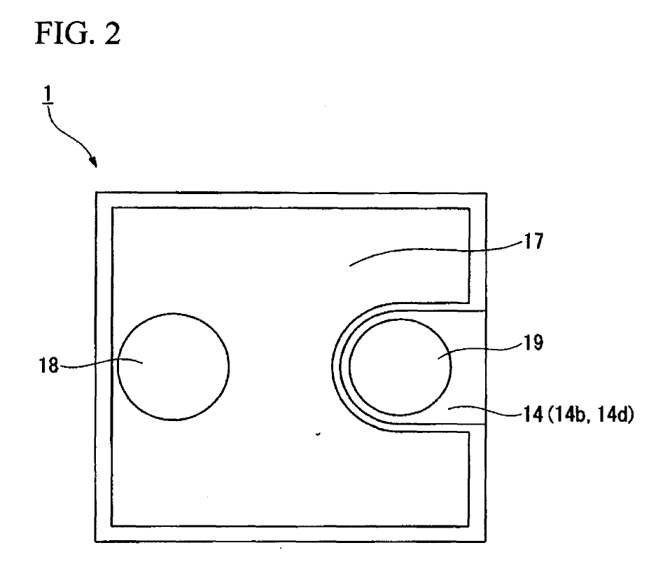

FIG. 1 is a schematic sectional view showing a Group II nitride compound semiconductor light-emitting device according to an embodiment of the invention, and FIG. 2 is a schematic view showing a planar structure of the Group III nitride compound semiconductor light-emitting device shown in FIG. 1.

As shown in FIG. 1, a light-emitting device 1 according to this embodiment is of a one-surface electrode type and includes a substrate 11, an intermediate layer 12 and a semiconductor layer 20 composed of a Group III nitride compound semiconductor containing Ga as a Group III element. As shown in FIG. 1, the semiconductor layer 20 includes an n type semiconductor layer 14, a light-emitting layer 15 and a p type semiconductor layer 16, which are laminated in order.

Laminated Structure of Light-Emitting Device: SUBSTRATE

The material forming the substrate 11 of the light-emitting device 1 is not particularly limited, but may be optional as long as Group III nitride compound semiconductor crystals can be epitaxially grown on a surface of the substrate 11. Examples of the material may include sapphire, SiC, silicon, zinc oxide, magnesium oxide, manganese oxide, zirconium oxide, manganese oxide zinc iron, magnesium-aluminum oxide, zirconium diboride, gallium oxide, indium oxide, lithium-gallium oxide, lithium-aluminum oxide, neodymium-gallium oxide, lanthanum-strontium-aluminum-tantalum oxide, strontium-titanium oxide, titanium oxide, hafnium, tungsten, and molybdenum.

When the intermediate layer 12 is formed using an oxide substrate or a metal substrate, which is known to cause a chemical modification when it contacts ammonia at a high temperature, without using ammonia, and then a base layer forming the n type semiconductor layer 14, which will be described layer, is formed on the intermediate layer 12 by a method of using ammonia, the intermediate layer 12 serves as a coating layer which effectively prevents the substrate 11 from being chemically modified, details of which will be described later.

In general, since a sputtering method can keep the temperature of the substrate 11 low, even when the substrate 11 is made of a material which may be decomposed at a high temperature, it is possible to form layers on the substrate 11 without damaging the substrate 11.

Intermediate Layer

In the light-emitting device 1, the intermediate layer 12 made of an aggregate of pillar-like crystals of a Group III nitride compound is formed on the substrate 11. The intermediate layer 12 is used to protect the substrate 11 against a chemical reaction at a high temperature, alleviate a difference in lattice constant between the substrate 11 and the semiconductor layer 20, or promote nucleation for crystal growth of the semiconductor layer 20.

The intermediate layer 12 covers at least 60%, preferably more than 80%, more preferably more than 90% of a surface 11a of the substrate 11. It is most preferable that the intermediate layer 12 be formed so as to cover 100% of the surface 11a of the substrate 1.

A smaller area of the intermediate layer 12 covering the surface 11a of the substrate 12 means a larger exposure of the substrate 11. This may cause a larger difference in lattice constant between a base layer 14a formed on the intermediate layer 12 and a base layer 14a directly formed on the substrate 11, which may result in non-uniform crystals and generation of hillocks or pits.

The intermediate layer 12 may be formed to cover a lateral side and/or a rear side of the substrate 11 in addition to the surface 11a of the substrate 11.

Semiconductor Layer

As shown in FIG. 1, the semiconductor layer 20 includes the n type semiconductor layer 14, the light-emitting layer 15 and the p type semiconductor layer 16.

A semiconductor laminated structure may be laminated on the base layer 14a composed of a Group III nitride compound semiconductor. For example, when a semiconductor laminated structure for a light-emitting device is formed, an n type conductive layer doped with an n type dopant, such as Si, Ge, or Sn, or a p type conductive layer doped with a p type dopant, such as Mg, may be lamina on the base layer 14a. InGaN may be used as a material forming a light-emitting layer or the like, and AlGaN may be used as a material forming a clad layer or the like. In this manner, when a Group III nitride semiconductor crystal layer having additional functions is formed on the base layer 14a, it is possible to manufacture a water having a semiconductor laminated structure, which is used to manufacture a light-emitting diode, a laser diode, or other electronic devices.

n Type Semiconductor Layer

The n type semiconductor layer 14 is laminated on the intermediate layer 12 and includes the base layer 14a, an n type contact layer 14b and an n type clad layer 14c. The n type contact layer 14b may serve as the base layer 14a and/or the n type clad layer 14c, or the base layer 14a may serve as the n type contact layer 14b and/or the n type clad layer 14c.

Base Layer

The base layer 14a of the n type semiconductor layer 14 is made of a Group III nitride compound semiconductor. Although it may be either the same as or different from the material forming the intermediate layer 12, the material forming the base layer 14a is preferably a Group III nitride compound containing Ga, that is, a GaN compound, more preferably AlₓGa₁₋ₓN (0≦x≦1, preferably 0≦x≦0.5, more preferably 0≦x≦0.1).

If necessary, the base layer 14a may be doped with n type impurities of 1×10¹⁷ to 1×10¹⁹/cm³ or may be preferably undoped (less than 1×10¹⁷/cm³ from the aspect of good crystallization.

For example, when the substrate 11 has a conductive property, electrodes can be formed on upper and lower sides of the light-emitting device 1 by making the base layer 14a conductive by doping a dopant into the base layer 14a On the other hand, when the substrate 11 is made of an insulating material, a chip structure is formed in which positive and negative electrodes are provided on the same surface of the light-emitting device 1. Therefore, it is preferable that a layer immediately above the substrate 11 be made of undoped crystals from the aspect of good crystallization.

The n type impurities are not particularly limited but may include, for example, Si, Ge, and Sn, preferably Si and Ge.

n Type Contact Layer

The n type contact layer 14b is made of a Group III nitride compound semiconductor. Similar to the base layer 14a, the material forming the n type contact layer 14b is preferably formed of AlₓGa₁₋ₓN (0≦x≦1, preferably 0≦x≦0.5, more preferably 0≦x≦0.1).

The n type contact layer 14b is preferably doped with n type impurities of 1×10¹⁷ to 1×10¹⁹/cm³, preferably 1×10¹⁸ to 1×10¹⁹/cm³ from the aspect of good ohmic contact with the cathode, prevention of cracks and good crystallization. The n type impurities are not particularly limited but may include, for example, Si, Ge, and Sn, preferably Si and Ge.

The gallium nitride compound semiconductors forming the base layer 14a and the n type contact layer 14b preferably have the same composition, and the total film thickness of these layers 14a and 14b is 0.1 to 20 μm, preferably 0.5 to 15 μm, more preferably 1 to 12 μm. This film thickness range gives good semiconductor crystallization.

n Type Clad Layer

The n type clad layer 14c is preferably provided between the n type contact layer 14b and the light-emitting layer 15. The n type clad layer 14c can provide an effect of supplying electrons to an activated layer, alleviating a lattice constant difference, etc.

The n type clad layer 14c can be formed of AlGaN, GaN, GaInN, etc. and may have a hetero junction of these compounds or a multi-laminated super lattice structure of these compounds. When the n type clad layer 14c is made of GaInN, a band gap of GaInN of this layer 14c is preferably wider than that of GaInN of the light emitting layer 15.

The n type dope density of the n type clad layer 14c is preferably 1×10¹⁷ to 1×10²⁰/cm³, more preferably 1×10¹¹ to 1×10¹⁹/cm³. This range of dope density is desirable from the aspect of good crystallization and reduction of operation voltage of the light-emitting device.

Light-Emitting Layer

The light-emitting layer 15 is formed between the n type semiconductor layer 14 and the p type semiconductor layer 16. The light-emitting layer 15 may have a multi quantum well structure, a single well structure, a bulk structure or the like. In this embodiment, as shown in FIG. 1, the light-emitting layer 15 includes barrier layers 15a made of a gallium nitride compound semiconductor and well layers 15b made of a gallium nitride compound semiconductor in a repeated manner, with the barrier layers 15a facing the n type semiconductor layer 14 and the p type semiconductor layer 16, respectively. In the example shown in FIG. 1, the light-emitting layer 15 has the multi quantum well structure in which six barrier layers 15a and five well layers 15b are alternately laminated, with the barrier layers 15a as the uppermost and lowermost layers and with the well layers 15b interposed between the barrier layers 15a.

Each of the barrier layers 15a is preferably made of a gallium nitride compound semiconductor such as Al_{c}Ga_{1-c}N (0≦c<0.3) having band gap energy more than that of the well layers 15b.

Each of the well layers 15b is preferably made of a gallium nitride compound semiconductor that contains indium, for example, a gallium-indium nitride such as Ga₁₋ₛInₛN (0<s<0.4).

p Type Semiconductor Layer

The p type semiconductor layer 16 includes a p type clad layer 16a and a p type contact layer 16b. The p type contact layer 16b may serve as the p type clad layer 16a.

p Type Clad Layer

The p type clad layer 16a has the composition having band gap energy more than that of the light-emitting layer 15. The material forming the p type clad layer 16a is not particularly limited as long as it can block carriers of the light-emitting layer 15, but may be preferably Al_{d}Ga_{1-d}N (0<d≦0.4, preferably 0.1<d≦0.3). As the material forming the p type clad layer 16a, AlGaN is desirable since it can block carriers of the light-emitting layer 15.

The p type dope density of the p type clad layer 16a is preferably 1×10¹⁸ to 1×10²¹/cm³, more preferably 1×10¹⁹ to 1×1²⁰/cm³. This range of p type dope density gives good p type crystals without deterioration of crystallization. The p type impurities ae not particularly limited but may be preferably Mg.

p Type Contact Layer

The p type contact layer 16b is a gallium nitride compound semiconductor layer containing at least AlₑGa₁₋ₑN (0≦e<0.5, preferably 0≦e≦0.2, more preferably 0≦e≦0.1). This range of Al composition is desirable from the aspect of good crystallization and good ohmic contact with a p ohmic electrode (see a transmissive electrode 17 which will be described later).

The p type contact layer 16b is preferably doped with a p type dopant of 1×10¹⁸ to 1×10²¹/cm³, more preferably 5×10¹⁹ to 1×10²⁰/cm³ from the aspect of good ohmic contact, prevention of cracks and good crystallization. The p type impurities are not particularly limited but may include, for example, Mg.

The semiconductor layer 20 of the light-emitting device 1 is not limited to the above-described embodiment.

In addition to the above-mentioned materials, for example, gallium nitride compound semiconductors expressed by a general formula Al_{X}Ga_{Y}In_{Z}n_{1-A}M_{A} (0≦X≦1, 0≦Y≦1, 0≦Z≦1, X+Y+Z=1, M represents a Group V element other than nitrogen (N), and 0≦A<1) are known as a material forming the semiconductor layer. In this embodiment, these known gallium nitride compound semiconductors may be used without any limitation.

The Group III nitride compound semiconductor containing Ga as a Group III element may contain other Group III elements, and if necessary, Ge, Si, Mg, Ca, Zn, Be, P and As, in addition to Al, Ga and In. In addition, without being limited to the above-mentioned elements, in some cases, this Group III nitride compound semiconductor may contain unavoidable impurities under film forming conditions and a very small quantity of impurities included in raw materials and material of a reaction tube.

Transmissive Anode

The transmissive anode 17 is a transmissive electrode formed on the p type semiconductor layer 16.

The material forming the transmissive anode 17 is not particularly limited but may include, for example, ITO (In₂O₃—SnO₂), AZO (ZnO—Al₂O₃), IZO (In₂O₃—ZnO), GZO (ZnO—Ga₂O₃). The transmissive anode 17 may have any structures including known structures without any limitation.

The transmissive anode 17 may be formed to cover the entire surface of the p type semiconductor layer 16 and may be formed in a lattice or resin shape.

Anode Bonding Pad

An anode bonding pad 18 is a substantially circular electrode formed on the transmissive anode 17, as shown in FIG. 2.

Various known structures using Au, Al, Ni, Cu, etc. may be used as a material forming the anode bonding pad 18, without any limitation.

The thickness of the anode bonding pad 18 is preferably in a range of 100 to 1000 nm. Since a thicker bonding pad gives higher bondability, the thickness of the anode bonding pad 18 is more preferably more than 300 nm. The thickness of the anode bonding pad 18 is preferably less than 500 nm from the aspect of product costs.

Cathode

A cathode 19 is in contact with the n type contact layer 14b of the n type semiconductor layer 14 constituting the semiconductor layer 20. Accordingly, as shown in FIGS. 1 and 2, the cathode 19 is formed in a substantially circular shape on an exposed region 14d which is formed by removing portions of the p type semiconductor layer 16, the light-emitting layer 15, and the n type semiconductor layer 14 and through which the n type contact layer 14b is exposed.

As the material for the cathode 19, cathodes of various compositions and constitutions are known and those known cathodes may be employed without any restrictions.

Now, prior to description of a method of manufacturing the light-emitting device of the invention, an apparatus and method for manufacturing the semiconductor layer of the light-emitting device will be first described.

Apparatus for Manufacturing Semiconductor Layer of Light-Emitting Device

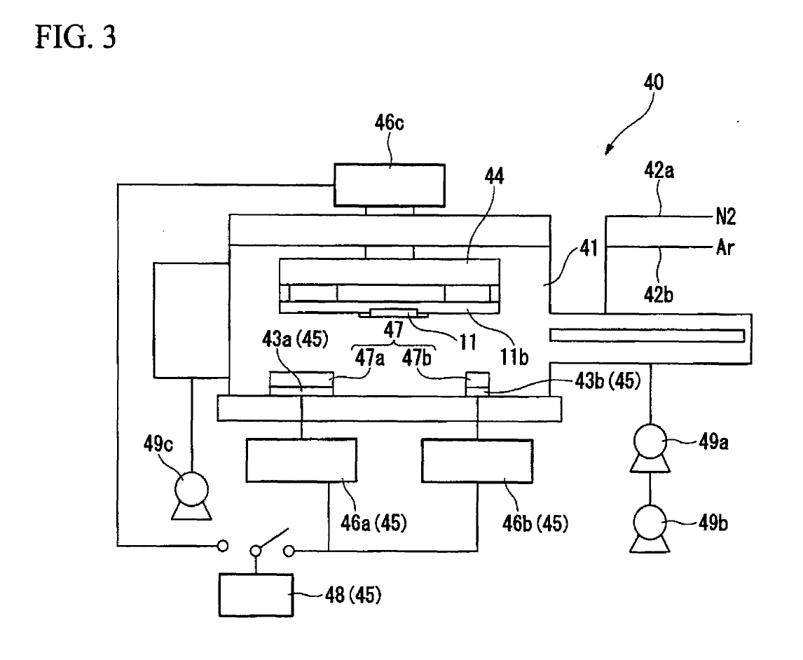

FIG. 3 is a schematic view showing an example of an apparatus for manufacturing a Group III nitride compound semiconductor light-emitting device according to an embodiment of the invention. An apparatus 40 for manufacturing the Group III nitride compound semiconductor light-emitting device (hereinafter also abbreviated as a light-emitting device) shown in FIG. 3 is used to form a semiconductor layer, which constitutes a light-emitting device made of a Group III nitride compound semiconductor containing Ga as a Group III element, on the substrate 11 by means of a sputtering method.

As shown in FIG. 3, the light-emitting device manufacturing apparatus 40 includes a chamber 41, a sputter target 47 provided within the chamber 41, and power application means 45 for applying power to the sputter target 47. In addition, as shown in FIG. 3, the chamber 41 of the light-emitting device manufacturing apparatus 40 includes therein a holder 11b for holding the substrate 11 downward facing the sputter target 47, and a heater 44 for heating the substrate 11. Outside the chamber 41 are provided a matching box 46c electrically connected to the holder 11b, a power supply 48 electrically connected to the matching box 46c, pressure control units 49a, 49b and 49c such as pumps for controlling pressure within the chamber 41, and gas supply units 42a and 42b for introducing gas into the chamber 41.

In this embodiment, as shown in FIG. 3, the sputter target 47 includes a Ga target 47a and a dopant target 47b composed of dopant elements. The Ga target 47a is placed on an electrode 43a for applying power to the Ga target 47a, and the dopant target 47b is placed on an electrode 43b for applying power to the dopant target 47b.

The Ga target 47a may be composed of only Ga, or may further contain other elements in addition to Ga depending on the composition of the formed semiconductor layer. In this embodiment, the Ga target 47a may be in a solid state or a liquefied state. In the case of the liquefied state, the entire or only one surface of the Ga target 47a may be liquefied.

In the light-emitting device manufacturing apparatus 40 shown in FIG. 3, the dopant target 47b may include dopant elements, such as, Si, Ge, Sn, Mg, Be, Zn, Cd, and Ca. The dopant target 47b is preferably Si if the semiconductor layer to be formed is of an n type, while it is preferably Mg if the semiconductor layer to be formed is of a p type. However, the invention is not limited thereto.

The power application means 45 applies power to the Ga target 47a and the dopant target 47b simultaneously or alternately. As shown in FIG. 3, the power application means 45 includes the electrodes 43a and 43b, the matching boxes 46a and 46b electrically connected to the electrodes 43a and 43b, and the power supply 48 electrically connected to the matching boxes 46a and 46b. The power applied to the Ga target 47a can be adjustable through the matching box 46a, while the power applied to the dopant target 47b can be adjustable through the matching box 46b. That is, the power applied to the Ga target 47a and the dopant target 47b can be controlled either individually or independently.

In this embodiment, power is applied to the Ga target 47a and the dopant target 47b by a pulse DC method or an RF (radio frequency) method. When the light-emitting device manufacturing apparatus 40 shown in FIG. 3 is used to form the semiconductor layer by means of a reactive sputtering method, it is preferable to apply the RF power to the targets 47a and 47b since a film forming rate can be controlled with ease. When the light-emitting device manufacturing apparatus 40 shown in FIG. 3 is used to form the semiconductor layer by means of the reactive sputtering method, if continuous DC power is applied to the Ga target 47a and the dopant target 47b, these targets 47a and 47b may be charged up, thereby making it difficult to increase a film forming rate. Accordingly, it is preferable to apply the pulse DC power, which provides a pulsed bias, to these targets 47a and 47b.

In this embodiment, the matching boxes 46a and 46b of the power application means 45 can control the ratio of Ga to dopants in a gas phase when the semiconductor layer is formed, by changing the ratio of the power applied to the Ga target 47a to the power applied to the dopant target 47b and accordingly changing the amount of particles of Ga and dopant supplied in the gas phase.

Since the ratio of Ga to dopants in crystals of the formed semiconductor layer is constant, the doping density in crystals of the formed semiconductor layer can be controlled by controlling the amount of particles of Ga and dopants supplied in the gas phase.

Here, the ratio of the power applied to the Ga target 47a to the power applied to the dopant target 47b can be arbitrarily changed by controlling the power supplied to the matching boxes 46a and 46b.

When the pulse DC power is applied, the matching boxes 46a and 46b of the power application means 45 can control the ratio of Ga to dopants in a gas phase when the semiconductor layer is formed, by changing the pulse ratio of the pulse applied to the Ga target 47a to the pulse applied to the dopant target 47b and accordingly changing the amount of particles of Ga and dopants supplied in the gas phase.

Here, the pulse ratio of the pulse applied to the Ga target 47a to the pulse applied to the dopant target 47b can be arbitrarily changed by controlling the on/off time of power supplied to the matching boxes 46a and 46b.

If the dopant is Si, it is preferable that the ratio of Ga to dopant (Ga:Si) in the gas phase when the semiconductor layer is formed be controlled to fall within a range of 1:0.001 to 1:0.00001 by means of the power application means 45.

If the dopant is Mg, it is preferable that the ratio of Ga to dopant (Ga:Mg) in the gas phase when the semiconductor layer is formed be controlled to fall within a range of 1:0.1 to 1:0.001 by means of the power application means 45.

The light-emitting device manufacturing apparatus 40 shown in FIG. 3 can sputter the dopant target 47b such that a cluster including diatomic or more dopant elements cannot be formed.

It is preferable that the dopant elements be uniformly distributed in crystals of the Group III nitride compound semiconductor in order to generate carriers efficiently. In order to uniformly distribute the dopant elements in the crystals, it is preferable that the dopant elements in the crystals be dispersed and doped in a monoatomic state. If the dopant elements in crystals of the Group II nitride compound semiconductor exist as a cluster including diatoms or more, it is believed that the dopant elements cannot generate carriers effectively.

When the dopant elements are supplied by sputtering the dopant target 47b, if kinetic energy of sputter particles impacting on the dopant target 47b such as Ar is too large, the dopant elements may be forced out of the dopant target 47b as a cluster. Accordingly, it is preferable to sputter the dopant target 47b with increased kinetic energy of the sputter particles so that a cluster cannot be formed. Specifically, in order that the cluster is not formed, there may be used an apparatus and method for sufficiently decreasing a voltage to accelerate the sputter particles impacting on the dopant target 47b or a method using elements having small atomic weight as the sputter particles.

In this embodiment, as the power application means 45 controls the voltage to accelerate the sputter particles impacting on the dopant target 47b, a cluster including diatomic or more dopant elements cannot be formed when the dopant target 47b is sputtered.

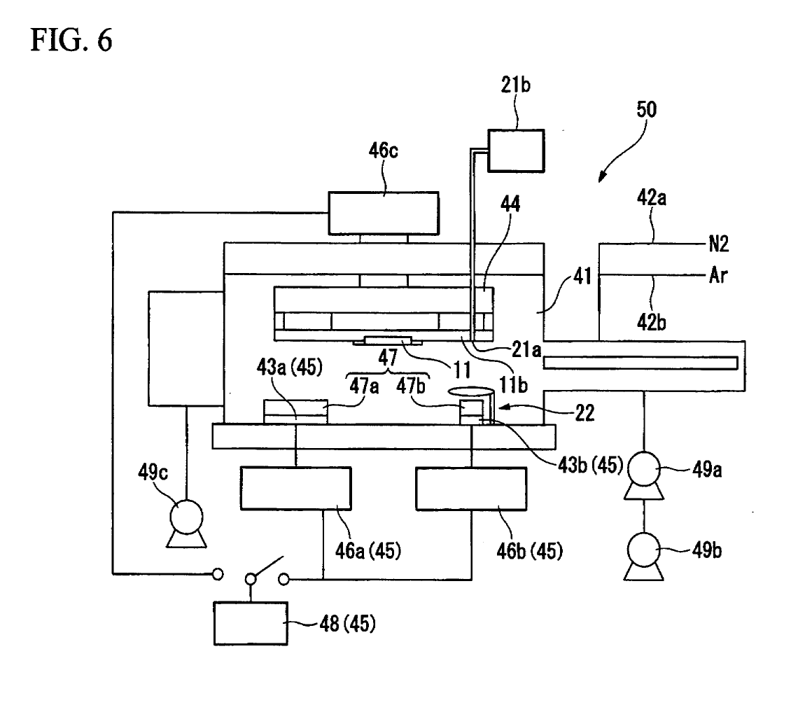

For example, in the case of RF sputtering, power to generate plasma may be applied over the target and an inner wall. In this case, plasma may not be generated if a voltage to pull the sputter particles to the target is decreased. Accordingly, it is preferable to use a manufacturing apparatus which is capable of controlling power to generate the plasma and the voltage to pull the sputter particles to the target separately. Specifically, for example, a manufacturing apparatus 50 shown in FIG. 6 is preferably used.

FIG. 6 is a schematic view showing another example of the apparatus for manufacturing a Group III nitride compound semiconductor light emitting device according to an embodiment of the invention. In FIG. 6, the same members as those in FIG. 3 are denoted by the same reference numerals, and a description thereof will be omitted. The manufacturing apparatus 50 shown in FIG. 6 includes an RF dielectric coupling plasma generator 22 installed above the dopant target 47b in the chamber 41. In the manufacturing apparatus 50 shown in FIG. 6, the voltage to accelerate the sputter particles impacting on the dopant target 47b can be arbitrarily set by generating plasma in the RF dielectric coupling plasma generator 22.

In the manufacturing apparatus 50 shown in FIG. 6, it may be determined whether or not a cluster including diatomic or more dopant elements is formed. The manufacturing apparatus 50 shown in FIG. 6 includes an intake port 21a provided near the substrate 11 in the chamber 41, and a mass spectrometer 21b connected to the intake port 21a through a pipe. In the manufacturing apparatus 50 shown in FIG. 6, particles generated by sputtering the dopant target 47b are inhaled by the intake port 21a and measured by the mass spectrometer 21b.

For example, when a dopant is Si, a peak of a mass spectrum appears with the mass number of 28 if particles including dopant elements, which are inhaled by the intake port 21a, are monoatoms, while a peak of mass spectrum appears with the mass number of 56 if the particles are diatomic molecules.

Although it has been illustrated in this embodiment that the mass spectrometer is used to determine whether or not the cluster including diatomic or more dopant elements is formed, such a determination may be made using plasma spectroscopy or other apparatuses and methods. In the plasma spectroscopy, although different elements give different emission wavelengths, an emission spectrum may be covered by a background, thereby making it difficult to separate the emission spectrum. In addition, in the plasma spectroscopy, since an emission spectrum does not appear due to an element or there is little spectral difference between cluster and non-cluster of particles, it may be difficult to determine whether or not the cluster is formed. Accordingly, rather than the plasma spectroscopy, the mass spectrometer is preferably used to determine whether or not the cluster is formed.

As described above, the light-emitting device manufacturing apparatus 40 shown in FIG. 3 includes the sputter target 47 including the Ga target 47a and the dopant target 47b, and the power application means to apply power to the Ga target 47a and the dopant target 47b simultaneously or alternately. Accordingly, the ratio of Ga to dopant in a gas phase when the semiconductor layer is formed can be arbitrarily controlled by means of the power application means 45, and it is possible to easily optimize the density of dopant elements in crystals of the Group III nitride compound semiconductor containing Ga.

In the light-emitting device manufacturing apparatus 40 shown in FIG. 3, if at least a surface of the Ga target 47a is in a liquefied state, since particles having high energy can be taken out and supplied on the substrate 11, it is possible to more efficiently grow the semiconductor layer, which is made of the Group III nitride semiconductor having good crystallization, on the substrate 11. Also, if at least a surface of the Ga target 47a is in a liquefied state, since the Ga target 47a can be uniformly used without being partially biased, the material forming the Ga target 47a can be efficiently used.

In general, when a layer made of several materials is formed on a substrate by means of a sputtering method, a sputter including chambers whose number is equal to that of material targets, each chamber having one target, is used to form the layer on the substrate while moving the substrate between the chambers. However, the sputter used for this method has a disadvantage in that it increases in size due to an increase in the number of chambers and it takes a long time to form the layer.

In contrast, the manufacturing apparatus of this embodiment includes the Ga target 47a and the dopant target 47b in the chamber, and applies power to the Ga target 47a and the dopant target 47b simultaneously or alternately using the power application means. Accordingly, the structure of the manufacturing apparatus is simplified and it is possible to reduce the time required to form the layer, since it is unnecessary to move the substrate between chambers as in the sputter in which one target is placed in each chamber.

Although the manufacturing apparatus 40 including two sputter targets such as the Ga target 47a and the dopant target 47b in the chamber 41 has been illustrated in this embodiment, as shown in FIG. 3, the manufacturing apparatus of the invention is not limited to this embodiment.

For example, if a plurality of semiconductor layers having different compositions is formed on the substrate, a plurality of targets corresponding to different compositions of the semiconductor layers is provided in the same chamber, which makes it possible to continuously form the semiconductor layers having the different compositions on the substrate in the same chamber. This configuration of the manufacturing apparatus makes it possible to simplify the manufacturing apparatus, reduce a processing time, and perform a film forming process with high efficiency.

In the light-emitting device manufacturing apparatus 40 shown in FIG. 3, since the dopant target 47b is sputtered such that the cluster is not formed, it is possible to manufacture the Group III nitride compound semiconductor in which dopant elements are uniformly dispersed and doped in crystals in a monoatomic state and which is capable of generating carriers efficiently.

In addition, in the light-emitting device manufacturing apparatus 40 shown in FIG. 3, since the dopant target 47b is sputtered with a voltage to form no cluster, it is possible to control kinetic energy of sputter particles with ease and sputter the dopant target 47b without forming any clusters.

Manufacturing Method of Semiconductor Layer of Light-Emitting Device

In this embodiment, as an example of the light-emitting device manufacturing method using the manufacturing apparatus 40 shown in FIG. 3, a method of forming the semiconductor layer of the light-emitting device on the substrate 11 by means of a reactive sputtering method will be described.

When the manufacturing apparatus 40 shown in FIG. 3 is used to form the semiconductor layer of the light-emitting device on the substrate 11 by means of the sputtering method, first, the pressure control units 49a, 49b and 49c set the inside of the chamber 41 to a predetermined pressure and the gas supply units 42a and 42b introduce a predetermined amount of Ar gas and activated gas as a nitride raw material into the chamber 41, thereby placing the chamber 41 under a certain atmosphere.

The internal pressure of the chamber 41 is preferably not less than 0.3 Pa. If the internal pressure of the chamber 41 is less than 0.3 Pa, the amount of nitrogen becomes too small, and thus, sputtered metal is likely to adhere to the substrate 11 before the sputtered metal becomes a nitride. The internal pressure of the chamber 41 is not particularly limited but may be set to a pressure high enough to generate plasma.

In this embodiment, the nitride raw material used as the activated gas may be generally known nitride compounds without any limitation, but is preferably ammonia or nitrogen (N₂) because of its ease of handling and low price.

Although ammonia has good decomposition efficiency and makes it possible to form a film at a high growth rate, it has high reactivity and toxicity. Accordingly, the use of ammonia requires deharmanising equipment or a gas sensor. In addition, the material for members used in a reactor has to have high chemical stability.

The use of nitrogen (N₂) cannot provide a high reaction speed although a simple processing apparatus may be used. However, when nitrogen is decomposed by an electric field or heat and then introduced into an apparatus, it is possible to obtain a film forming rate sufficient to be industrially utilized although it is lower than a reaction speed of ammonia. Accordingly, considering a balance with apparatus costs, nitrogen (N₂) is most suitable as the activated gas.

Next, a heater station 44 is heated by means of a heating means (not shown) provided in the heater station 44, and the substrate 11 is heated to a predetermined temperature, that is, a growth temperature at which a semiconductor layer is optimally grown on the substrate 11.

The temperature of the substrate 11 in forming the semiconductor layer is preferably in the range of room temperature to 1200° C., more preferably 300 to 1000° C., most preferably 500 to 800° C. Here, room temperature is in a range of 0 to 30° C. although it may be affected by process environments.

If the temperature of the substrate 11 is lower than the lower limit, migration on the substrate 11 is suppressed, which makes it difficult to form a semiconductor layer having good crystallization. If the temperature of the substrate 11 is higher than the upper limit, crystals of the semiconductor layer may be decomposed.

With the substrate 11 heated, current is supplied to the electrodes 43a and 43b through the matching boxes 46a and 46b, power is applied to the Ga target 47a and the dopant target 47b simultaneously or alternately, current is supplied to the holder 11b, and a bias voltage is applied to the substrate 11.

Then, in a gas phase in the chamber 41, particles including Ga elements are forced out of the Ga target 47a, and particles including dopant elements are forced out of the dopant target 47b. The particles including Ga elements or dopant elements in the gas phase impact on and are deposited on the surface of the substrate 11 held by the holder 11b, thereby forming the semiconductor layer on the substrate 11.

In this embodiment, the dopant target 47b is sputtered at a voltage at which a cluster including diatomic or more dopant elements cannot be formed.

Here, the ratio of Ga to dopant in the gas phase when the semiconductor layer is formed is controlled by changing the amount of particles of Ga and dopant supplied in the gas phase using at least one of the following three methods.

(1) Controlling the area ratio of a surface (upper surface in FIG. 3) of the Ga target 47a facing the substrate 11 to a surface (upper surface in FIG. 3) of the dopant target 47b facing the substrate 11.

(2) Controlling the ratio of power applied to the Ga target 47a to power applied to the dopant target 47b. Here, the ratio of power applied to the Ga target 47a to power applied to the dopant target 47b can be changed by controlling power supplied to the matching boxes 46a and 46b.

(3) Applying pulse DC power and controlling the ratio of pulse applied to the Ga target 47a to pulse applied to the dopant target 47b. Here, the ratio of pulse applied to the Ga target 47a to pulse applied to the dopant target 47b can be changed by controlling the on/off time of power supplied to the matching boxes 46a and 46b.

For example, when an n type semiconductor layer is formed on the substrate 11 using the manufacturing apparatus 40 shown in FIG. 3, it is preferable that Si be used as the dopant, and the ratio of Ga to Si in the gas phase in forming the semiconductor layer be set within a range of 1:0.001 to 1:0.00001 using at least one of the above-mentioned methods (1) to (3).

This makes it possible to control the doping density in the n type semiconductor layer using Si as the dopant to fall within a range of 1×10¹⁷ cm⁻³ to 1×10¹⁹ cm⁻³.

In addition, for example, when a p type semiconductor layer is formed on the substrate 11 using the manufacturing apparatus 40 shown in FIG. 3, it is preferable that Mg be used as the dopant, and the ratio of Ga to Mg in the gas phase in forming the conductor layer be set within a range of 1:0.1 to 1:0.001 using at least one of the above-mentioned methods (1) to (3).

This makes it possible to control the doping density in the p type semiconductor layer using Mg as the dopant to fall within a range of 1×10¹⁹ cm⁻³ to 1×10²¹ cm⁻³.

In addition, if an ambient temperature of the Ga target 47a in the sputter 40 when the semiconductor layer is formed is not lower than 29° C., the Ga target 47a may be liquefied since Ga is metal having a low melting point of 29° C. If an ambient temperature of the Ga target 47a in the sputter 40 when the semiconductor layer is formed is lower than 29° C., the Ga target 47a may be solidified.

If the Ga target 47a is in a solid state when the semiconductor layer is formed, it is preferable to liquefy at least one surface of the Ga target 47a.

As a method of liquefying the Ga target 47a, there may be used for example a method of applying power above a predetermined level to the Ga target 47a. Here, power applied to the Ga target 47a in order to liquefy the Ga target 47a is preferably not less than 0.1 W/cm². When power not less than 0.1 W/cm² is applied to the Ga target 47a, the Ga target 47a can be reliably liquefied since the surface of the Ga target 47a is exposed to plasma although the Ga target 47a is in the solid sate.

If the power applied to the Ga target 47a is less than 0.1 W/cm², the Ga target 47a may not be liquefied when the Ga target 47a is in the solid sate.

As another method of liquefying the Ga target 47a, there may be used for example a method of heating the Ga target 47a by means of heating means. In this case, the heating means is not particularly limited, and may be, for example, an electric heater.

In this embodiment, the power applied to the Ga target 47a is preferably in a range of 0.1 W/m² to 100 W/cm², more preferably 1 W/cm² to 50 W/cm², most preferably 1.5 W/cm² to 50 W/cm².

With this range of power applied to the Ga target 47a, reactive species having high power can be generated and supplied to the substrate 11 with high kinetic energy. This activates migration on the substrate 11 and makes it easy to loop a potential so that the semiconductor layer does not inherit crystallization of a base layer.

In this embodiment, a film forming rate in forming the semiconductor layer is preferably in a range of 0.01 nm/s to 10 nm/s. If the film forming rate is less than 0.01 nm/s, it takes a long time to perform a film forming process. If the film forming rate is more than 10 nm/s, it is difficult to obtain a high-quality film.

In the manufacturing method of this embodiment, when the semiconductor layer is formed using the sputtering method, the Ga target 47a and the dopant target 47b are used and the power is applied to the Ga target 47a and the dopant target 47b simultaneously or alternately. Therefore, it is possible to easily optimize the doping density of the dopant in the crystals of the Group III nitride compound semiconductor containing Ga and form the semiconductor layer with high efficiency using the sputtering method.

In addition, in the manufacturing method of this embodiment, since the semiconductor layer is formed using the sputtering method, it is possible to increase the film forming rate and reduce the time required to form (manufacture) the semiconductor layer, as compared to a MOCVD (metal organic chemical vapor deposition) method. The reduction of manufacturing time may prevent impurities from being introduced into the chamber, thereby obtaining a good semiconductor layer with less contamination.

In addition, since the reactive sputtering method of supplying the activated gas as the nitride raw material into the chamber is used as the manufacturing method of this embodiment, the obtained semiconductor layer has good and uniform crystallization.

In addition, in the manufacturing method of this embodiment, when at least a surface of the Ga target 47a is liquefied, particles having high energy can be taken out and supplied on the substrate 11. Therefore, it is possible to grow the semiconductor layer made of the Group III nitride semiconductor having good crystallization on the substrate 11 with higher efficiency.

Also, if at least a surface of the Ga target 47a is in a liquefied state, the Ga target 47a can be uniformly used without being partially biased. Therefore, the material forming the Ga target 47a can be efficiently used.

In addition, in the manufacturing method of this embodiment, although the reactive sputtering method of supplying the activated gas as the nitride raw material into the chamber has been illustrated, the present invention is not limited to the reactive sputtering method.

In addition, although this embodiment has been illustrated with the preferred manufacturing apparatus and method for sputtering the dopant target 47b at the voltage at which a cluster including diatomic or more dopant elements is not formed, such as the method of setting the voltage causing the sputter particles to impact on the target to be low and the method of controlling the voltage causing the sputter particles to impact on the target to be low and the plasma generation voltage separately using the RF dielectric coupling plasma generator installed in the chamber, the present invention is not limited to the manufacturing apparatus and method in which a cluster is not formed. For example, the sputter may supply dopant elements including monoatoms and clusters.

The manufacturing method of the invention is not limited to the above-described embodiment. For example, when the semiconductor layer is formed, a method of rotating or rocking a magnetic field applied to the Ga target 47a and the dopant target 47b may be employed. Movement of a magnet used for this method may be optional depending on the kind of sputter. For example, the magnet may be either rocked or rotated.

In addition, the semiconductor layer may be formed to cover either a lateral side or a rear surface of the substrate 11 in addition to the front surface of the substrate 11.

As a method of forming the semiconductor layer on the front surface and the lateral side of the substrate 11, there may be used a method of forming the semiconductor layer on the substrate 11 while changing the position of the substrate 11 facing the Ga target 47a and the dopant target 47b by rocking or rotating the substrate 11. This method allows the semiconductor layer to be formed on the entire surface of the substrate 11 using two processes, that is, the first process of forming the semiconductor layer on the front surface and the lateral side of the substrate 11 at once, and the second process of forming the semiconductor layer on the rear surface of the substrate 11. As another method of forming the semiconductor layer on the front surface and the lateral side of the substrate 11, there may be used a method of forming the entire surface of the semiconductor layer on the substrate 11 by placing the substrate 11 within the chamber 41, instead of holding the substrate 11 by means of the holder.

In addition, if the Ga target 47a and the dopant target 47b have a large area and are movable, the semiconductor layer may be formed on the entire surface of the substrate 11 without moving the substrate 11. As such a method, there may be used an RF (radio frequency) sputtering method of forming the semiconductor layer on the substrate 11 while moving magnets of the Ga and dopant targets 47a and 47b in the targets by rocking or rotating the magnets.

When the semiconductor layer is formed using the RF sputtering method, there may be used a method of moving both the substrate 11 and the Ga and dopant targets 47a and 47b. In addition, by placing the Ga and dopant targets 47a and 47b near the substrate such that generated plasma is not supplied to the substrate 11 in the form of a beam, but surrounds the substrate, it is possible to form the semiconductor layer on the surface and lateral side of the substrate 11 at once.

Manufacturing Method of Light-Emitting Device

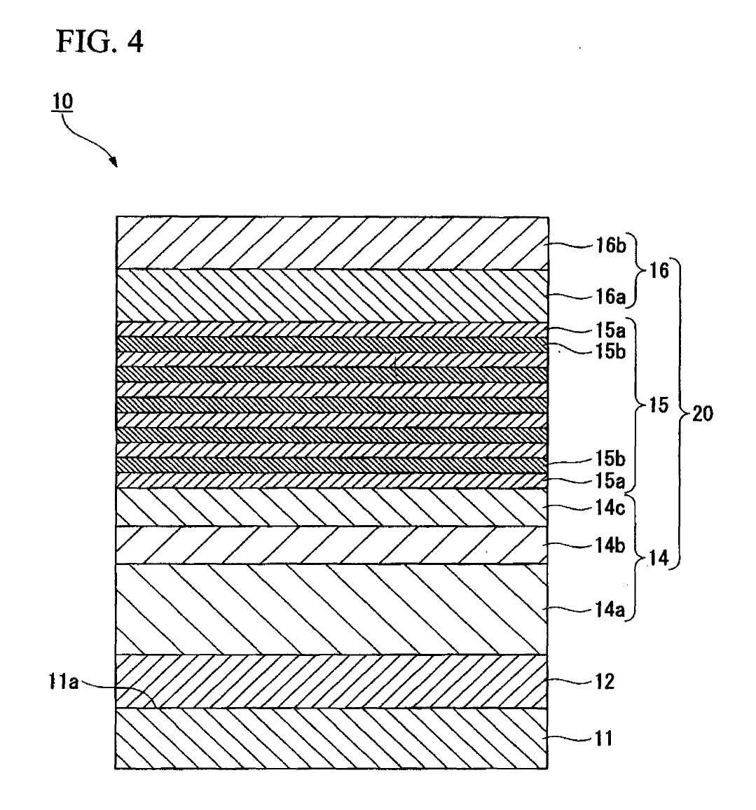

In order to manufacture the light-emitting device 1 shown in FIG. 1, first, a laminated semiconductor 10 including the semiconductor layer 20, as shown in FIG. 4, is formed on the substrate 11. In order to form the laminated semiconductor 10 shown in FIG. 4, firs, the substrate 11 is prepared. The substrate 11 is preferably subjected to pre-treatment.

For pre-treatment of the substrate 11, for example, if the substrate 11 is made of silicon, there may be used a method of hydrogen-terminating a surface of the substrate 11 using a wet method such as a known RCA cleaning method. This stabilizes the film forming process.

In addition, the pre-treatment of the substrate 11 may be made according to a method of placing the substrate 11 within the chamber of the sputter and sputtering the substrate 11 before forming the intermediate layer 12. Specifically, in the chamber, pre-treatment to clean the surface of the substrate 11 may be performed by exposing the substrate 11 to Ar or N₂ plasma. When the Ar or N₂ plasma is applied to the surface of the substrate 11, it is possible to remove organic matter or oxides adhered to the surface of the substrate 11. In this case, when a voltage is applied between the substrate 11 and the chamber without application of power to the target, plasma particles are efficiently applied to the substrate 11.

After the pre-treatment of the substrate 11, the intermediate layer 12 shown in FIG. 4 is formed on the substrate 11 using the sputtering method.

Thereafter, as in the above-described semiconductor layer manufacturing method, the base layer 14a and the n type contact layer 14b of the n type semiconductor layer 14 shown in FIG. 4 are continuously formed on the intermediate layer 12 formed on the substrate 11 by the reactive sputtering method using the above-described light-emitting device manufacturing apparatus 40 shown in FIG. 3.

First, the manufacturing apparatus 40 shown in FIG. 3, in which the substrate 11 having the intermediate layer 12 formed thereon, the Ga target 47a and the dopant target 47b including dopant elements are placed within the chamber 41, is prepared. Here, the dopant elements are n type impurities, such as Si, Ge, and Sn, used when the n type contact layer 14b is formed or when the base layer 14a and the n type contact layer 14b are formed.

Next, the inside of the chamber 41 is set to a predetermined pressure, a predetermined amount of Ar gas and activated gas as a nitride raw material is introduced into the chamber 41, the chamber 41 in which the base layer 14a is to be formed is placed under a certain atmosphere, and the substrate 11 is heated at a predetermined temperature.

Here, the temperature of the substrate 11 when the base layer 14a is formed, that is, the growth temperature of the base layer 14a, is preferably not less than 800° C. Such a high substrate temperature is likely to cause migration of atoms, thereby facilitating potential looping. In addition, since the temperature of the substrate 11 when the base layer 14a is formed is required to be lower than a temperature at which crystals are decomposed, the substrate temperature is preferably less than 1200° C. When the temperature of the substrate 11 falls within this temperature range when the base layer 14a is formed, the base layer 14a having good crystallization can be obtained.

When an undoped semiconductor layer is formed as the base layer 14a, a predetermined current is supplied to only the electrode 43a through the matching box 46a, power is applied to only the Ga target 47a without application of power to the dopant target 47b, a current is supplied to the holder 11b, a bias voltage is applied to the substrate 11, and the base layer 14a is formed on the intermediate layer 12 of the substrate 11 at a predetermined film forming rate.

When a doped semiconductor layer is formed as the base layer 14a, a predetermined current is supplied to the electrodes 43a and 43b through the matching boxes 46a and 46b, power is applied to the Ga target 47a and the dopant target 47b simultaneously or alternately, a current is supplied to the holder 11b, a bias voltage is applied to the substrate 11, and the base layer 14a is formed on the intermediate layer 12 of the substrate 11 at a predetermined film forming rate.

Subsequently, similar to when the base layer 14a composed of the doped semiconductor layer is formed, the inside of the chamber 41 is placed in a predetermined atmosphere in which the n type contact layer 14b is formed, and the substrate 11 having the base layer formed thereon is heated at a predetermined temperature. The n type contact layer 14b is formed at the same temperature as that at which the base layer 14a is formed. Also, similar to when the base layer 14a composed of the doped semiconductor layer is formed, power is applied to the Ga target 47a and the dopant target 47b simultaneously or alternately, and the n type contact layer 14b is formed on the base layer 14a of the substrate 11 at a predetermined film forming rate.

In addition, when the base layer 14a and the n type contact layer 14b are each formed of a doped semiconductor layer, dopant elements of these layers may be the same or different. If the dopant elements of the two layers are different, the light-emitting device manufacturing apparatus 40 including two dopant targets and two matching boxes and two electrodes for applying power to the dopant targets can easily form the two layers by selecting one of the dopant targets supplied with the power depending on dopant elements of the doped semiconductor layer to be formed.

Next, the n type clad layer 14c of the n type semiconductor layer 14, the light-emitting layer 15 including the barrier layer 15a and the well layer 15b, and the p type clad layer 16a of the p type semiconductor layer 16 are formed using a MOCVD (metal organic chemical vapor deposition) method providing good crystallization.

In the MOCVD method, hydrogen (H₂) or nitrogen (N₂) is used as a carrier gas, trimethylgallium (TMG) or triethylgallium (TEG) is used as a source of Ga as a Group III raw material, trimethylaluminum (TMA) or triethylaluminum (TEA) is used as an Al source, trimethylindium (TMI) or triethylindium (TEI) is used as an In source, and ammonia (NH₃) or hydrazine (N₂H₄) is used as a source of N as a Group V raw material.

For the n type impurities of the dopant elements, monosilane (SiH₄) or disilane (Si₂H₆) is used as a Si raw material, and organic germanium compounds such as a germane gas (GeH₄), tetramethylgermanum ((CH₃)₄Ge), tetraethylgermanum ((C₂H₅)₄Ge) and the like are used as a Ge raw material.

For the n type impurities of the dopant elements, biscyclopentadienylmagnesium (Cp₂Mg) or bisethylcyclopentadienylmagnesium (EtCp₂Mg) is used as an Mg raw material.

Next, the p type contact layer 16b of the p type semiconductor layer 16 is formed on the p type clad layer 16a of the p type semiconductor layer 16 by the reactive sputtering method using the above-described light-emitting device manufacturing apparatus 40 shown in FIG. 3.

The p type contact layer 16b of the p type semiconductor layer 16 is formed using p type impurities, such as Mg, as a dopant element of the dopant target 47b. More specifically, the inside of the chamber 41 is placed under a predetermined atmosphere in which the p type contact layer 16b is formed, and the substrate 11 having various layers up to the p type clad layer 16a formed thereon is heated at a predetermined temperature. Then, power is applied to the Ga target 47a and the dopant target 47b simultaneously or alternately, and the p-type contact layer 16b is formed at a predetermined film forming rate.

The transmissive anode 17 and the anode bonding pad 18 are sequentially formed on the p type contact layer 16b of the laminated semiconductor 10 obtained in this way, as shown in FIG. 4, using a photolithography method.

Next, the laminated semiconductor 10 having the transmissive anode 17 and the anode bonding pad 18 formed thereon is dry-etched to expose the exposed region 14d on the n type contact layer 14b.

Thereafter, the cathode 19 is formed on the exposed region 14d using a photolithography method, thereby completing the light-emitting device 1 shown in FIGS. 1 and 2.

In this embodiment, the light-emitting device can be manufactured with excellent productivity by forming the base layer 14a and the n type contact layer 14b of the n type semiconductor layer 14 and the p type contact layer 16b of the p type semiconductor layer 16 in the semiconductor layer 20 by the above-described sputtering method using the light-emitting device manufacturing apparatus shown in FIG. 3.

In addition, the light-emitting device of this embodiment provides the optimal doping density of dopant elements in crystals of the doped semiconductor layer of the base layer 14a and the n type contact layer 14b of the n type semiconductor layer 14 and the p type contact layer 16b of the p type semiconductor layer 16. Accordingly, the light-emitting device 1 of this embodiment has excellent emission properties.

In this embodiment, in the semiconductor layer 20 of the light-emitting device 1, only the base layer 14a and the n type contact layer 14b of the n type semiconductor layer 14 and the p type contact layer 16b of the p type semiconductor layer 16 are formed by the above-described sputtering method using the light-emitting device manufacturing apparatus shown in FIG. 3. However, the invention is not limited to this embodiment. For example, at least some layers of the semiconductor layer 20 may be formed using the same sputtering method.

Specifically, the n type clad layer 14c of the n type semiconductor layer 14 and the p type clad layer 16a of the p type semiconductor layer 16 are formed by the MOCVD in this embodiment, but the invention is not limited thereto. For example, the n type clad layer 14c of the n type semiconductor layer 14 and the p type clad layer 16a of the p type semiconductor layer 16 may be formed by the sputtering method of the invention.

In the light-emitting device 1 of the invention, at least some of the layers of the semiconductor layer 20 may be formed by the sputtering method of the invention, and the semiconductor layer 20 may be formed by combinations of the sputtering method of the invention and any methods for growing a semiconductor layer, such as a conventional sputtering method, a MOCVD (metal organic chemical vapor deposition) method, an HVPE (hydride gas phase epitaxy) method, and an UBE (molecular bean epitaxy) method.

The Group III nitride compound semiconductor light-emitting device of the invention can be used for photoelectric converting devices, such as laser devices and light receiving devices, electronic devices, such as HBTs and HEMTs, etc., in addition to the above-described light-emitting device. These semiconductor devices are known to have various structures. The structure of the Group III nitride compound laminated semiconductor 10 of the invention includes these known device structures without any limitation.

Lamp

A lamp of the invention employs the light-emitting device of the invention.

The lamp of the invention may include, for example, a combination of the light-emitting device of the invention and a phosphor. A lamp as a combination of a light-emitting device and a phosphor can be constructed in a manner known in the art using means known in the art. The lamp of the invention can employ conventionally known techniques for changing the color of emitted light by combining a light emitting device with a phosphor, without any limitation.

For example, it is possible to obtain light having a wavelength longer than that obtained in the light-emitting device by suitably selecting a phosphor used in the lamp. In addition, it is possible to obtain a lamp that emits white light by mixing the wavelength of light obtained in the light-emitting device with the wavelength converted by the phosphor.

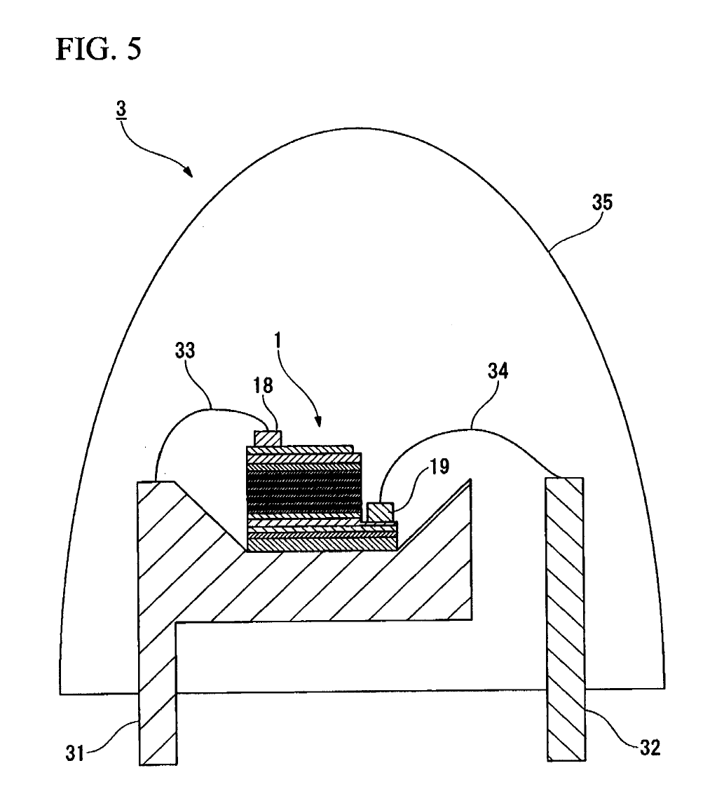

FIG. 5 is a schematic view showing an exemplary lamp employing a Group III nitride compound semiconductor light-emitting device according to an embodiment of the invention. A lamp shown in FIG. 5 has a shell shape and uses the light-emitting device 1 shown in FIG. 1. As shown in FIG. 5, the light-emitting device 1 is mounted by adhering an anode bonding pad 18 of the light-emitting device 1 to one (frame 31 in FIG. 5) of two frames 31 and 32 via a wire 33 and a cathode 19 of the light-emitting device 1 to the other frame 32 via a wire 34. The light-emitting device 1 is molded with a transparent resin 35.

The lamp employing the light-emitting device of the invention can be manufactured with high productivity and has excellent emission properties.

The lamp of the invention can be of various types including a general shell type, a side view type for a backlight of a mobile phone, a top view type for a display, etc.

### EXAMPLES

Hereinafter, this invention will be described in more detail with reference to several Examples and Comparative examples, but the invention is not limited thereto.

### Example 1

As described below, the laminated semiconductor 10 shown in FIG. 4 was manufactured and the light-emitting device shown in FIGS. 1 and 2 was manufactured.

First, the substrate 11 made of polished sapphire was prepared and subjected to pre-treatment as follows. That is, the substrate 11 was placed in a chamber for sputtering in which a target that is made of Al and is used to form the intermediate layer 12, the substrate 11 was heated at 500° C., and a nitrogen gas was introduced into the chamber at a flow rate of 15 sccm with the internal pressure of the chamber kept at 1.0 Pa. Then, an RF bias power of 50 W was applied to the substrate 11 without supplying power to the target, and a surface of the substrate 11 was cleaned by exposing the substrate 11 to nitrogen plasma.

After the pre-treatment, with the internal pressure of the chamber kept to 0.5 Pa, an argon gas and a nitrogen gas were introduced into the chamber at flow rates of 5 scam and 15 scam, respectively, (the percentage of nitrogen gas in the total gas was 75%) to set an atmosphere in which the intermediate layer 12 is formed. Next, with the substrate 11 kept at 500° C., a power of 1 W/cm² was applied to the Al target without supplying bias power to the substrate 11, and the intermediate layer 12 made of an aggregate of pillar-like crystals of AlN was formed with a thickness of 50 nm on the substrate at a film forming rate of 0.12 nm/s by a sputtering method.

Next, the substrate 11 having the intermediate layer 12 formed thereon was taken out of the sputter, and the base layer 14a made of undoped GaN and the n type contact layer 14b made of GaN doped with Si were sequentially formed by a reactive sputtering method using the light-emitting device manufacturing apparatus 40 shown in FIG. 3.

The substrate 11 having the intermediate layer 12 formed thereon, the Ga target 47a made of Ga, and the dopant target 47b made of Si were placed within the chamber 41 of the manufacturing apparatus 40 shown in FIG. 3. Here, the ratio of the area of the Ga target 47a to the area of the dopant target 47b exposed in the chamber was preset to 1:0.01 such that the density of Si in the n type contact layer 14b to be formed became 1×10¹⁹ cm⁻³.

Next, with the internal pressure of the chamber 41 kept to 0.5 Pa, an argon gas and a nitrogen gas were introduced into the chamber 41 at flow rates of 5 scan and 15 sccm, respectively, (the percentage of nitrogen gas in the total gas is 75%) to set an atmosphere in which the base layer 14a and the n type contact layer 14b were formed.

Next, the substrate 11 was heated at 1000° C. Thereafter, while sweeping a magnet in the Ga target 47a to vary a location at which a magnetic field is applied, power was supplied to the electrode 43a through the matching box 46a. In addition, a power of 1 W/cm² was applied to the Ga target 47a, power was supplied to the holder 11b including the heater 44, and, with an RF (radio frequency) bias power of 0.5 W/cm² supplied to the substrate 11, the base layer 14a was formed with a thickness of 6 μm on the substrate 11 at a film forming rate of 1 nm/s for 90 minutes.

Thereafter, under the same conditions of temperature and bias power as the substrate 11, a power of 1 W/cm² was continuously applied to the Ga target 47a and the Si target, and then, a film forming process is performed for 30 minutes. As a result, a 2 μm-thick n type contact layer 14b made of Ga doped with Si is formed on the base layer 14a.

The density of Si in the formed n type contact layer 14b is measured by a general SIMS (secondary ion mass spectrometry) method. As a result, it is confirmed that Si is doped at a density of 1×10¹⁹ cm⁻³.

Next, the substrate 11 having various layers up to the n type contact layer 14b of the n type semiconductor layer 14 formed thereon was introduced into a MOCVD furnace, and the n type clad layer 14c made of In_{0.02}Ga_{0.98}N doped with Si and the light-emitting layer 15 including the barrier layer 15a and the well layer 15b were formed on the n type contact layer 14b.

First, a 20 nm-thick n type clad layer 14c was formed on the n type contact layer 14b, and then, the light-emitting layer (having a multi quantum well structure) 15 including six 16 nm-thick barrier layers 15a each made of GaN and five 3 nm-thick well layers each made of In_{0.02}Ga_{0.8}N, which are alternately laminated, was formed on the n type clad layer 14c.

Next, the substrate 11 having various layers up to the final barrier layer 15b of the light-emitting layer 15 formed thereon was taken out of the MOCVD furnace, and the p type clad layer 16a and the p type contact layer 16b were formed on the light-emitting layer 15 by the reactive sputtering method using the light-emitting device manufacturing apparatus 40 shown in FIG. 3.

First, the p type clad layer 16a was formed. To begin with, as the chamber 41 used to form the p type clad layer 16a, a chamber 41 different from the chamber used to form the base layer 14a and the n type contact layer 14b was prepared, and the Ga target 47a made of Al and Ga and the dopant target 47b made of Mg were placed within the chamber 41. The ratio of Ga to Al in the Ga target 47a placed within the chamber 41 used to form the p type clad layer 16a was set to 7%. In addition, the ratio of the area of the Ga target 47a to the area of the dopant target 47b exposed in the chamber 41 was set to 1:0.01.

Then, the substrate 11 having various layers up to the final barrier layer 15b of the light-emitting layer 15 formed thereon was introduced into the chamber 41 used to form the p type clad layer 16a, and a current was supplied to the electrodes 43a and 43b through the matching boxes 46a and 46b. In addition, an RF (radio frequency) power of 1 W/cm² was applied to the Ga target 47a, and an RF power of 1.5 W/cm² was applied to the dopant target 47b without applying bias power to the substrate to form a 20 nm-thick p type clad layer 16a made of Al_{0.07}Ga_{0.93}N doped with Mg on the light-emitting layer 15 at a film forming rate of 1 nm/s.

Like the above-mentioned Si density, the density of Mg in the formed p type clad layer 16a was measured by a general SIMS method. As a result, it was confirmed that Mg is doped at a density of 1.5×10²⁰ cm⁻³.

Next, the p type contact layer 16b was formed. The Ga target 47a made of Al and Ga and the dopant target 47b made of Mg were placed within the chamber 41 used to form the p type contact layer 16b. The ratio of Ga to Al in the Ga target 47a placed within the chamber 41 used to form the p type contact layer 16b was set to 3%. In addition, the ratio of the area of the Ga target 47a to the area of the dopant target 47b exposed in the chamber 41 was set to 1:0.01.

Then, the substrate 11 having various layers up to the p type clad layer 16a formed thereon was introduced into the chamber used to form the p type contact layer 16b, and a current was supplied to the electrodes 43a and 43b through the matching boxes 46a and 46b. An RF (radio frequency) power of 1 W/cm² was applied to the Ga target 47a, and the same RF power of 1 W/cm² was also applied to the dopant target 47b without applying bias power to the substrate to form a 20 nm-thick p type contact layer 16b made of Al_{0.02}Ga_{0.98}N doped with Mg on the p type clad layer 16a at a film forming rate of 1 nm/s.

Like the above-mentioned Si density, the density of Mg in the formed p type contact layer 16b was measured by a general SIMS method. As a result, it was confirmed that Mg is doped at a density of 1×10²⁰ cm⁻³.

The transmissive electrode 17 made of ITO and the anode bonding pad 18 having a structure in which titanium, aluminum and gold are laminated in this order from the surface of the transmissive electrode 17 were sequentially formed on the p type contact layer 16b of the laminated semiconductor 10 obtained in this way, as shown in FIG. 4, using a photolithography method.

Next, the laminated semiconductor 10 having the transmissive electrode 17 and the anode bonding pad 18 formed thereon was dry-etched to expose the exposed region 14d from the n type contact layer 14b, and then, the cathode 19 composed of four layers of Ni, Al, Ti and Au was formed on the exposed region 14d using a photolithography method, thereby completing the light-emitting device 1 shown in FIGS. 1 and 2.

A rear side of the substrate 11 of the light emitting device 1 obtained in this way was ground and polished into a mirror shape, and then, the substrate 11 was cut into square chips each having a size of 350 μm. Then, the obtained chips were placed on a lead frame, with electrodes directing upward, and were connected to the lead frame by a gold wire, thereby obtaining a light-emitting diode.

A forward current flowed between the anode bonding pad 18 and the cathode 19 of the obtained light-emitting diode.

As a result, a forward voltage was 3.0 V when a current of 20 mA flowed. It was confirmed that the wavelength of light emitted from the transmissive electrode 17 of the p type semiconductor layer 16 is 460 nm and an emission power is 15 mW. It was confirmed that the light-emitting device 1 of Example 1 has excellent emission properties.

### Example 2

Using the light-emitting device manufacturing apparatus 50 shown in FIG. 6, under the same conditions as Example 1 except that the area ratio of the Ga target 47a to the dopant target 47b is 1:1 and the film forming conditions of the n type contact layer 14b are different, the laminated semiconductor 10 shown in FIG. 4 was manufactured and the light-emitting device shown in FIGS. 1 and 2 was manufactured.

More specifically, unlike Example 1, in Example 2, with the area of the Ga target 47a equal to the area of the dopant target 47b, the ratio of power applied to the Ga target 47a to power applied to the dopant target 47b was preset such that the density of Si in the n type contact layer 14b to be formed becomes 8×10¹⁸ cm⁻³. For example, RF power applied to the dopant target 47b was set to 1/100 of the RF power applied to the Ga target 47a, that is, 0.01 W/cm². At this time, plasma was generated by the RF dielectric coupling plasma generator 22 provided within the chamber 41 of the light-emitting device manufacturing apparatus 50 shown in FIG. 6, and a voltage applied to the dopant target 47b was set to 100 V. The conditions of bias power, substrate temperature, film forming rate and so on were the same as those in Example 1.

The density of Si in the formed n type clad layer 14b was measured by a general SIMS (secondary ion mass spectrometry) method. As a result, it was confirmed that Si is doped at a density of 8×10¹⁸ cm⁻³.

Like Example 1, the laminated structure obtained in this way was used as a light-emitting diode, and a forward current flowed between the anode bonding pad 18 and the cathode 19 of the light-emitting diode. As a result, a forward voltage was 3.2 V when a current of 20 mA flowed. It was confirmed that the wavelength of light emitted from the transmissive electrode 17 of the p type semiconductor layer 16 was 470 nm and an emission power was 13.5 mW. From his, it was confirmed that the light-emitting device 1 of Example 2 has an excellent emission property.

### Example 3

Using the same light-emitting device manufacturing apparatus 40 shown in FIG. 3 as that in Example 1, under the same conditions as those in Example 1 except for tee area ratio (1:1) of the Ga target 47a to the dopant target 47b and the film forming conditions of the n type contact layer 14b, the laminated semiconductor 10 shown in FIG. 4 was manufactured and the light-emitting device shown in FIGS. 1 and 2 was manufactured.

More specifically, unlike Example 1, in Example 3, with the area of the Ga target 47a equal to the area of the dopant target 47b, the ratio of pulse applied to the Ga target 47a to pulse applied to the dopant target 47b was preset such that the density of Si in the n type contact layer 14b to be formed becomes 1.1×10¹⁹ cm⁻³. For example, a pulse of RF power applied to the dopant target 47b was set to 1/100 of the pulse of RF power applied to the Ga target 47a. That is, while the Ga target 47a is continuously supplied with power, the dopant target 47b was supplied with power for 1 ms and then no power for 100 ms. The conditions of bias power, substrate temperature, film forming rate and so on were the same as those in Example 1.

The density of Si in the formed n type clad layer 14b was measured by a general SIMS (secondary ion mass spectrometry) method. As a result, it was confirmed that Si is doped at a density of 1.1×10¹⁹ cm⁻³.

Like Example 1, the laminated structure obtained in this way was used as a light-emitting diode, and a forward current flowed between the anode bonding pad 18 and the cathode 19 of the light-emitting diode. As a result, a forward voltage was 3.1 V when a current of 20 mA flowed. It was confirmed that the wavelength of light emitted from the transmissive electrode 17 of the p type semiconductor layer 16 was 470 nm and an emission power was 13.2 mW. From this, it was confirmed that the light-emitting device 1 of Example 3 has an excellent emission property.

### Example 4

Using the same light-emitting device manufacturing apparatus 40 shown in FIG. 3 as that in Example 1, under the same conditions as those in Example 1 except for the film forming conditions of the n type clad layer 14c, the laminated semiconductor 10 shown in FIG. 4 was manufactured and the light-emitting device shown in FIGS. 1 and 2 was manufactured.

More specifically, unlike Example 1, in Example 3, the Ga target 47a made of an alloy of In and Ga and the dopant target 47b made of Si were placed in the chamber. The ratio of the area of the Ga target 47a to the area of the dopant target 47b exposed in the chamber was set to 1:0.01. In addition, in the Ga target 47a made of a mixture of n and Ga, the composition ratio of In in an InGaN layer to be formed was set to 2%.

The n type clad layer 14c was formed as follows. The substrate 11 having each layer up to the n type contact layer 14b formed thereon was placed within the chamber 41 and heated at 700° C. Thereafter, while sweeping a magnet in the Ga target 47a to vary a location at which a magnetic field is applied, power was supplied to the electrode 43a through the matching box 46a. In addition, a power of 1 W/cm² was applied to the Ga target 47a, and an RF power of 0.1 W/cm² was applied to the Si target 47b intermittently at a time ratio of 1/10. Further, power was supplied to the holder 11b including the heater 44, and, with an RF (radio frequency) bias power of 0.5 W/cm² being applied to the substrate 11, the n type clad layer 14c was formed with a thickness of 20 nm on the substrate 11 at a film forming rate of 0.03 nm/s for 10 minutes.

The density of Si in the formed n type clad layer 14b was measured by a general SIMS (secondary ion mass spectrometry) method. As a result, it was confirmed that Si is doped at a density of 1×10¹⁷ cm⁻³.

Like Example 1, the laminated structure obtained in this way was used as a light-emitting diode, and a forward current flowed between the anode bonding pad 18 and the cathode 19 of the light-emitting diode. As a result, a forward voltage was 3.3 V when a current of 20 mA flowed. It was confirmed that the wavelength of light emitted from the transmissive electrode 17 of the p type semiconductor layer 16 is 470 nm and an emission power is 14.1 mW. From this, it was confirmed that the light-emitting device 1 of Example 4 has an excellent emission property.

### Comparative Example 1

Using the sputter having the chamber in which a sputter target containing Ga and granular Si is placed, under the same conditions as those in Example 1 except for the formation of the n type contact layer 14b of the laminated semiconductor 10, the light-emitting device 1 shown in FIGS. 1 and 2 was manufactured.

### Examples 1 to 3 and Comparative Example 1

The n type contact layer 14b of the light-emitting device 1 in Examples 1 to 3 and Comparative Example 1 was formed for one week, and then, a change in the amount of Si contained in the formed n type contact layer 14b was examined.

As a result of the examination the change in the amount of Si in Examples 1 to 3 was within a range of 1.01×10¹⁹ cm⁻³ to 0.99×10¹⁹ cm⁻³, while the change in the amount of Si in Comparative Example 1 was within a range of 0.8×10¹⁹ cm⁻³ to 1.5×10⁻¹⁹ cm⁻³.

The examination proves that the amount of Si contained in the n type contact layer 14b in Examples 1 to 3 can be accurately controlled and optimized, as compared to Comparative Example 1.

The n type contact layer 14b of the light-emitting device 1 in Examples 1 to 3 and Comparative Example 1 was formed for one week, and then, the Ga target 47a used to form to a type contact layer 14b was examined.

As a result of the examination, in either Examples 1 to 3 or Comparative Example 1, it was confirmed that the Ga target 47a is sometimes liquefied due to a variation in the power or temperature of cooling water.

At this time, in the Ga target 47a of Comparative Example 1, the granular Si rises over Ga because of a specific gravity difference between Si and Ga and is condensed.

From this, it was estimated that the variation in the amount of Si contained in the formed n type contact layer 14b in Comparative Example 1 is larger than that in Examples 1 to 3.

The amount of leaked current from the light-emitting device 1 in Examples 1 to 3 and Comparative Example 1 was examined.

As a result of the examination, leaked current when a backward voltage of 20 V is applied in Examples 1 to 3 was within a range of 1 μA to 3 μA, while leaked current in Comparative Example 1 was 10 μA.

The examination proved that crystallinity in Examples 1 to 3 is higher than that in Comparative Example 1.

The Group III nitride compound semiconductor light-emitting device of the invention includes a Group III nitride compound semiconductor layer having high crystallinity and has excellent emission properties. Accordingly, it is possible to manufacture semiconductor devices, such as light-emitting diodes, laser diodes, and electronic devices, having excellent emission properties.

1. An apparatus for manufacturing a Group III nitride compound semiconductor light-emitting device including a semiconductor layer made of a Group III nitride semiconductor using a sputtering method, comprising:
a chamber;
a Ga target containing a Ga element and a dopant target containing a dopant element, the Ga target and the dopant target being placed within the chamber; and
a power application unit that applies power to the Ga target and the dopant target simultaneously or alternately.

2. The apparatus according to claim 1, wherein the dopant element is Si or Mg.

3. The apparatus according to claim 1,
wherein the power application unit controls a ratio of the Ga element to the dopant element in a gas phase when the semiconductor layer is formed, by changing a ratio of power applied to the Ga target to power applied to the dopant target.

4. The apparatus according to claim 1,
wherein the power application unit applies pulse DC power and controls a ratio of the Ga element to the dopant element in a gas phase when the semiconductor layer is formed, by changing a pulse ratio of a pulse applied to the Ga target to a pulse applied to the dopant target.

5. The apparatus according to claim 3,
wherein the dopant element is Si, and
the power application unit controls a ratio of the Ga element to the Si element in the gas phase when the semiconductor layer is formed to fall within a range of 1:0.001 to 1:0.00001.

6. The apparatus according to claim 3,
wherein the dopant element is Mg, and
the power application unit controls a ratio of the Ga element to the Mg element in the gas phase when the semiconductor layer is formed to fall within a range of 1:0.1 to 1:0.001.

7. The apparatus according to claim 1, wherein at least a surface of the Ga target is liquefied.

8. The apparatus according to claim 1, wherein the dopant element is sputtered so that a cluster including a diatomic or more dopant element is not formed.

9. The apparatus according to claim 1,
wherein the dopant element is sputtered at a voltage at which the cluster including the diatomic or more dopant element is not formed.

10. A method of manufacturing a Group III nitride compound semiconductor light-emitting device including a laminated semiconductor layer having an n type semiconductor layer, a light-emitting layer, and a p type semiconductor layer, each made of a Group III nitride semiconductor, the method comprising the steps of:
forming at least some of the layers of the laminated semiconductor layer by a sputtering method; and
applying power to a Ga target containing a Ga element and a dopant target containing a dopant element simultaneously or alternately when the laminated semiconductor layer is formed by the sputtering method, the Ga target and the dopant target being used as sputter targets.

11. The method according to claim 10,
wherein the n type semiconductor layer is formed using Si as the dopant element.

12. The method according to claim 11,
wherein a ratio of the Ga element to the Si element in a gas phase when the n type semiconductor layer is formed falls within a range of 1:0.001 to 1:0.00001.

13. The method according to claim 10,
wherein the p type semiconductor layer is formed using Mg as the dopant element.

14. The method according to claim 13,
wherein a ratio of the Ga element to the Mg element in a gas phase when the p type semiconductor layer is formed falls within a range of 1:0.1 to 1:0.001.

15. The method according to claim 10,
wherein the ratio of the Ga element to the dopant element in the gas phase when the semiconductor layer is formed is controlled by changing an area ratio of a surface of the Ga target facing a substrate to a surface of the dopant target facing the substrate.

16. The method according to claim 10,
wherein the ratio of the Ga element to the dopant element in the gas phase when the semiconductor layer is formed is controlled by changing a ratio of power applied to the Ga target to power applied to the dopant target.

17. The method according to claim 10,
wherein the ratio of the Ga element to the dopant element in the gas phase when the semiconductor layer is formed is controlled by changing a ratio of the pulse of pulse DC power applied to the Ga target to the pulse of pulse DC power applied to the dopant target.

18. The method according to claim 10,
wherein an intermediate layer consisting of columnar crystals is formed between the substrate and the semiconductor layer.

19. The method according to claim 10,
wherein at least a surface of the Ga target is liquefied.

20. A Group III nitride compound semiconductor light-emitting device manufactured by the manufacturing method according to claim 10.

21. A lamp employing the Group III nitride compound semiconductor light-emitting device according to claim 20.
